(19) United States
(12) Patent Application Publication
(10) Pub. No.: US 2013/0020641 A1
(43) Pub. Date: Jan. 24, 2013

(54) SUBSTRATE FOR DISPLAY PANEL, MANUFACTURING METHOD OF SAME, DISPLAY PANEL, AND DISPLAY DEVICE

(71) Applicant: Yasutomo Nishikawa, Osaka (JP)

(72) Inventor: Yasutomo Nishikawa, Osaka (JP)

(73) Assignee: SHARP KABUSHIKI KAISHA, Osaka (JP)

(21) Appl. No.: 13/583,442

(22) PCT Filed: Dec. 17, 2010
(86) PCT No.: PCT/JP2010/072795

§ 371 Date: Sep. 7, 2012

(30) Foreign Application Priority Data
Mar. 16, 2010 (JP) 2010-059860

(51) Int. Cl. H01L 27/12; H01L 21/283

(52) U.S. Cl. 257/347; 438/609; 257/E27.112; 257/E21.159

(57) ABSTRACT

The present invention provides: a display panel substrate that has an excellent boundary surface adhesion between an insulating film and electrodes formed on the substrate, that particularly requires a configuration in which the lower electrode, the insulating film, and an upper electrode are layered on the substrate in this order from the substrate side, and that includes an auxiliary metal wiring for reducing the wiring resistance, where detachment between the lower electrode and the insulating film is sufficiently suppressed when the lower electrode must be made of ITO; a method for manufacturing such a display panel substrate; and a display panel and a display device including such a display panel substrate. A display panel substrate of the present invention has a lower electrode, an insulating film, and an upper electrode layered thereon in this order from the substrate side. The lower electrode has a region in which an electrode made of indium tin oxide (ITO) and electrode made of indium zinc oxide (IZO) are layered in this order from the substrate side.

### TECHNICAL FIELD

The present invention relates to a display panel substrate, a method for manufacturing the same, and a display panel and a display device. More particularly, the present invention relates to a display panel substrate that can be used for liquid crystal display devices, EL (Electroluminescence) display devices, and the like and that is suitably applicable to active matrix systems using thin film transistors (TFTs), and also relates to a method for manufacturing such a display panel substrate, and to a display panel and a display device.

### BACKGROUND ART

Display panel substrates have a transparent substrate with various electrodes, elements, and the like disposed thereon for driving the liquid crystals and the like. In general, the display panel substrates have a plurality of electrode layers formed thereon together with insulating films for insulating the electrode layers from each other. Among these display panel substrates, active matrix type substrates using thin film transistors (TFT) are employed for manufacturing various display devices, and the demand for such substrates is on the rise. Such active matrix type substrates are used for, for example, liquid crystal display devices, EL display devices, and the like employed in portable phones, PDAs (portable data transmission terminal), game devices, and the like.

Disclosed conventional display panel substrates are those in liquid crystal display devices where liquid crystals are held between a pair of substrates that are facing each other, a pair of electrodes are disposed over one of the pair of substrates via an insulating film to drive the liquid crystals, and the insulating film has a compressive stress that is at least 0N/cm² and no greater than 5×10⁴N/cm² (see Patent Document 1, for example).

Such liquid crystal display devices are configured to improve the display quality by suppressing the variation of the insulating film adhesion and by suppressing the insulating film formed over one of the substrates from being detached from the pair of electrodes (an upper electrode and a lower electrode) disposed in place through the insulating film.

### RELATED ART DOCUMENTS

### Patent Documents

Patent Document 1: Japanese Patent Application Laid-Open Publication No. 2009-47839

### SUMMARY OF THE INVENTION

### Problems to be Solved by Invention

However, in the case of the display panel substrate described above, regarding the adhesion of the insulating film formed between the pair of electrodes, i.e., the upper electrode (upper layer electrode) and the lower electrode (lower layer electrode), it was found that if the lower electrode is made of indium tin oxide (ITO), the insulating film detachment occurs at the boundary surface between the insulating film and the lower electrode even if the insulating film is under a compressive stress of at least 0N/cm² and no greater than 5×10⁴N/cm² (for example, as shown in FIG. 6, an insulating film 112 separates from a lower electrode 109). In this case, the detachment of the insulating film from the electrode causes display quality deterioration, lower yields, and lower reliability.

Here, in the case of display panel substrates, normally, indium tin oxide (ITO) films or indium zinc oxide (IZO) films are used as the electrodes, and silicon-containing inorganic insulating films such as silicon nitride films, silicon oxide films, or silicon oxynitride films are used as the insulating film. Therefore, the problem of detachment of the ITO film from these silicon films, and detachment of the IZO film from these silicon films arises. However, the upper electrode (upper layer electrode) of the pair of electrodes is unlikely to separate from the insulating film whether the electrode is an ITO film or an IZO film and, as a result, the problem of delamination virtually does not occur. On the other hand, it was found that the lower electrode (lower layer electrode) made of ITO is prone to separate from the insulating film, but the lower electrode made of IZO is unlikely to separate from the insulating film and therefore the problem of delamination virtually does not occur.

As described above, regarding the lower electrode of the pair of electrodes and the insulating film, if the lower electrode is made of ITO, the insulating film is prone to separate and if the lower electrode is made of IZO, the insulating film is unlikely separate. Therefore, in this sense, it is desirable to employ IZO as the material of the lower electrode.

However, if the lower electrode is made of ITO, switching from the ITO lower electrode to an IZO lower electrode can require process change, and that can be difficult. Also, ITO is particularly preferred in some cases. For example, when an auxiliary metal wiring (Al/Mo or the like) for the purpose of reducing the wiring resistance needs to be installed, in essence, IZO cannot be used, because the etchant of IZO and the etchant of Al/Mo are the same (SLA), and IZO would be etched when the auxiliary metal wiring is etched. In that case, ITO must be used to form a lower electrode, and therefore the problem of detachment of the insulating film from the lower electrode is unavoidable.

The present invention was devised in consideration of the problems described above, and is aiming at providing: a display panel substrate that has an excellent boundary surface adhesion between an insulating film and electrodes formed over the substrate, that particularly requires a configuration in which the lower electrode, the insulating film, and an upper electrode are layered over the substrate in this order from the substrate side, and that includes an auxiliary metal wiring for reducing the wiring resistance, wherein detachment between the lower electrode and the insulating film is sufficiently suppressed when the lower electrode must be made of ITO; a method for manufacturing such a display panel substrate; and a display panel and a display device including such a display panel substrate.

### Means for Solving the Problems

Regarding the display panel substrate having a plurality of electrode layers formed thereon and an insulating film formed between the electrode layers, the inventor of the present invention studied the boundary surface adhesion between the insulating film and the electrode layers. In the course of the study, the inventor focused attention on a display panel substrate configured to include a lower electrode (lower layer electrode), an insulating film, and an upper electrode (upper layer electrode) layered thereon in this order from the substrate side, and on the boundary surface adhesion between the lower electrode and the insulating film, and between the upper electrode and the insulating film. The inventor then found that, as described above, the upper electrode, whether it is made of an ITO film or an IZO film, is unlikely to separate from the insulating film, but the lower electrode made of ITO is prone to separate from the insulating film, and the lower electrode made of IZO is unlikely to separate from the insulating film. However, if an auxiliary metal wiring for reducing the wiring resistance (Al/Mo or the like) needs to be included, for example, and an IZO lower electrode is used, the above-mentioned problem would arise, and therefore the entire lower electrode should not be formed only of IZO. The inventor consequently discovered that an appropriate configuration is that the lower electrode has a region where an ITO electrode and an IZO electrode are layered in this order from the substrate side. As a result, the above-mentioned problems have been admirably solved, leading to completion of the present invention.

That is, the present invention is a display panel substrate having, on a substrate, a lower electrode, an insulating film, and an upper electrode layered thereon in this order from a side of the substrate, where the lower electrode includes a region in which an electrode made of indium tin oxide (ITO) and an electrode made of indium zinc oxide (IZO) are layered in this order from the substrate side.

In the above-mentioned display panel substrate, the lower electrode is divided into at least two layers, and preferably, from the substrate side, the first layer of the lower electrode is an ITO electrode (first lower electrode), and the second layer of the lower electrode is an IZO electrode (second lower electrode). In this specification, of the two-layered lower electrode, the layer proximal to the substrate is a first lower electrode, and the layer distal to the substrate (disposed on the insulating film side) is a second lower electrode. If the lower electrode is constituted of more than two layers, the layer in contact with the insulating film is a second lower electrode, and other layers proximal to the substrate are first lower electrodes. When an auxiliary metal wiring is included, preferably layers in contact with the auxiliary metal wiring are first lower electrodes.

In the present invention, the lower electrode preferably includes a region where an electrode made of ITO and an electrode made of IZO are layered in this order from the substrate side over the entirety of the lower electrode. However, only a portion of the lower electrode may be constituted of the layered structure of ITO and IZO. That is, the lower electrode is not prohibited from including both a region where an electrode made of ITO and an electrode made of IZO are layered in this order from the substrate side and a region constituted of an electrode region solely made of ITO or constituted of an electrode region solely made of IZO.

In the configuration in which a lower electrode, an insulating film, and an upper electrode are layered on the substrate in this order from the substrate side, normally, the lower electrode is formed to contact the substrate, and when an auxiliary metal wiring is to be included, the auxiliary metal wiring is formed in a portion of the lower electrode region such that the wiring is in contact the lower electrode, and the insulating film is either formed to contact the lower electrode or formed to contact both the lower electrode and the auxiliary metal wiring. Also, normally, the upper electrode is formed to contact the insulating film.

The configuration of the above-mentioned display panel substrate is not particularly limited as long as the above-mentioned primary constituting elements are included. The configuration may include, as necessary, other layers such as electrodes between the bottom side (substrate side) of the first lower electrode and the substrate, or between the first lower electrode and the second lower electrode. Also, as long as at least a portion of the top surface (the side opposite from the substrate) of the second lower electrode is in contact with the insulating film, another layer such as an electrode may be disposed between the top surface of the second lower electrode and the insulating film.

The bottom surface of the upper electrode may optionally be in contact with the insulating film. However, normally, at least a portion of the bottom surface or the entire bottom surface is in contact with the insulating film.

The upper electrode of the above-mentioned display panel substrate is preferably constituted of a transparent electrode made of ITO, IZO, or the like. The lower electrode is, as described above, preferably constituted of a layered structure of ITO and IZO. The electrode made of ITO is not limited to those that do not substantially include any impurities or those that do not include any other compound containing metals. The electrode made of ITO only needs to be an electrode substantially constituted of ITO to the degree considered to produce the effect of the present invention. The same applies to IZO. The electrode made of IZO only needs to be an electrode substantially constituted of IZO.

A preferred configuration of the present invention is that the above-mentioned display panel substrate has an auxiliary metal wiring disposed thereon between the substrate and the insulating film.

The objective of this configuration is to reduce the resistance by employing the auxiliary metal wiring and to improve the display performance and display quality by blocking any influence of signal delays and the like. Also, as described above, a lower electrode solely made of IZO cannot be used sometimes, even though it is desirable to use IZO as the lower electrode to avoid the issue of delamination from the insulating film, because normally the etchant of IZO and the etchant of the auxiliary metal wiring are the same (SLA), and therefore IZO is unavoidably etched when the auxiliary metal wiring is etched. The configuration described above, however, solves this problem. In this respect, the lower electrode with layered structure of ITO and IZO has a special technological significance.

In the above-mentioned configuration including an auxiliary metal wiring, preferably, the region over the substrate where the auxiliary metal wiring is formed includes a region where an electrode made of ITO (first lower electrode), an auxiliary metal wiring, an electrode made of IZO (second lower electrode), an insulating film, and an upper electrode are layered in this order from the substrate side.

Also preferably, the region other than the region where the auxiliary metal wiring is formed includes a region where an electrode made of ITO (first lower electrode), an electrode made of IZO (second lower electrode), an insulating film, and an upper electrode are layered in this order from the substrate side.

Preferably, in the above-mentioned display panel substrate, the substrate, the first lower electrode, the auxiliary metal wiring, the second lower electrode, and the insulating film are layered such that they are in contact with each other over a portion of the region or the entire region. However, a preferable configuration is a layered structure in which, substantially, the entire bottom surface (the surface facing the substrate) of the auxiliary metal wiring is in contact with the top surface (the surface on the side opposite from the substrate) of the first lower electrode, and the entire top surface (the surface on the side opposite from the substrate) of the auxiliary metal wiring is in contact with the bottom surface (the surface facing the substrate) of the second lower electrode.

With this configuration, adhesion between the first lower electrode layer and the auxiliary metal wiring layer, between the auxiliary metal wiring layer and the second lower electrode layer, between the second lower electrode layer and the insulating film layer, and between the insulating film layer and the upper electrode layer can be improved, and therefore the detachment can sufficiently be suppressed.

The auxiliary metal wiring is preferably formed of at least one selected from the group consisting of aluminum and aluminum alloys. The auxiliary metal wiring may also have a multi-layered structure containing these metals as a part. For example, an auxiliary metal wiring composed of aluminum (Al) and molybdenum (Mo) (i.e., Al/Mo) is preferred.

The insulating film used in the display panel substrate of the present invention is preferably a silicon-containing inorganic insulating film. This can be a film formed of a silicon-containing inorganic compound having an insulation property, which is used in the field of electronic substrate technology.

The silicon-containing inorganic insulating film is preferably made of a silicon-containing inorganic compound, for example, containing at least one selected from the group consisting of silicon nitride, silicon oxide, and silicon oxynitride. More preferably, it is one of the insulating films formed of such silicon-containing inorganic compounds, or constituted of layers of such insulating films.

The above-mentioned display panel substrate is preferably an active matrix type substrate using thin film transistors. Such active matrix type is preferred for the basic configuration of the display panel substrate of the present invention. That is, the active matrix type can suitably be applied to the configuration in which a lower electrode, an insulating film, and an upper electrode are layered in this order from the substrate side, and also to a configuration where, preferably, an auxiliary metal wiring is further included.

In the configuration described above, preferably the lower electrode and upper electrode are applied as at least one selected from the group consisting of the wiring, the pixel electrode, and the common electrode connected to thin film transistor.

Another aspect of the present invention is a method for manufacturing a display panel substrate having, on a substrate, a lower electrode, an insulating film, and an upper electrode layered thereon in this order from a side of the substrate, the method including: laminating a first lower electrode layer made of indium tin oxide (ITO) (first lower electrode) and a second lower electrode layer made of indium zinc oxide (IZO) (second lower electrode) in this order from the substrate side, and where the first lower electrode layer and the second lower electrode layer are patterned using the same photomask.

Because the same photomask is used for patterning according to the method for manufacturing described above, the manufacturing process efficiency can be improved. Also, when an auxiliary metal wiring is to be disposed, as described below, the configuration can include a region where the first lower electrode, the auxiliary metal wiring, the second lower electrode, and the insulating film are layered in this order from the substrate side.

The lamination process described above is preferably conducted in the following order: forming the first lower electrode of ITO; forming the second lower electrode of IZO; depositing the insulating film; and forming the upper electrode. Also, when an auxiliary metal wiring is disposed, the auxiliary metal wiring is preferably formed before the insulating film is deposited. In particular, preferably the second lower electrode layer made of IZO is formed after the first lower electrode (ITO) and the auxiliary metal wiring (Al/Mo or the like) are formed, and then, the insulating film is formed on the second lower electrode. More specifically, preferably the first lower electrode (ITO) formation, the auxiliary metal wiring (Al/Mo or the like) formation, the second lower electrode (IZO) formation, the insulating film deposition, and the upper electrode (ITO or IZO) formation are conducted in this order.

This way, the auxiliary metal wiring (Al/Mo or the like) for reducing the resistance is formed on the first lower electrode, and also the second lower electrode (IZO) for improving the adhesion to the insulating film, which insulating film is disposed over the first lower electrode and the auxiliary metal wiring, is formed. Thus, adhesion to the insulating film is greatly improved, and detachment between the lower electrode and the insulating film is prevented or sufficiently suppressed.

Yet another aspect of the present invention is a display panel including the display panel substrate of the present invention.

Yet another aspect of the present invention is a display device including the display panel of the present invention.

In the above-mentioned display panel and the display device including the above-mentioned display panel, as described above, adhesion to the insulating film is greatly improved, and detachment between layers disposed on the display panel substrate can be suppressed. As a result, in many cases, effects such as better display quality, higher yields, and improved reliability can be produced.

Constituting elements of the display panel substrate of the present invention, the method for manufacturing the same, and a display panel and a display device including the same are not particularly limited as long as the above-mentioned constituting elements are employed as primary members. Any constituting elements that can be employed in the field of the display panel substrate technology can also be used as appropriate.

Configurations described above may appropriately be combined within the scope of the present invention.

### Effects of the Invention

According to the display panel substrate of the present invention and the method for manufacturing the same, in a substrate required to have a configuration in which a lower electrode, an insulating film, and an upper electrode are layered on the substrate in this order from the substrate side, detachment between the lower electrode and the insulating film is sufficiently suppressed.

### BRIEF DESCRIPTION OF THE DRAWINGS

FIG. 1 is a cross-sectional view schematically showing the structure of a thin film transistor used in a display panel substrate of an embodiment.

FIG. 2 is a cross-sectional view schematically showing the lamination structure of the display panel substrate of an embodiment.

FIG. 3 is a plan view schematically showing the display panel substrate of an embodiment.

FIG. 4 is an exploded perspective view showing the structure of a liquid crystal panel of an embodiment.

FIG. 5 is an exploded perspective view schematically showing the structure of a liquid crystal display device of the liquid crystal panel shown in FIG. 4.

FIG. 6 is a cross-sectional view schematically showing the layered structure of an electrode of a conventional display panel substrate.

### DETAILED DESCRPTION OF EMBODIMENTS

The substrate on which the thin film transistor elements (TFT) are disposed in an embodiment is also referred to as TFT substrate.

The substrate on which color filters (CF) are disposed in an embodiment is also referred to as CF substrate.

The present invention is further described in detail below using embodiments and with reference to figures. However, the present invention is not limited only to these embodiments.

### Embodiment 1

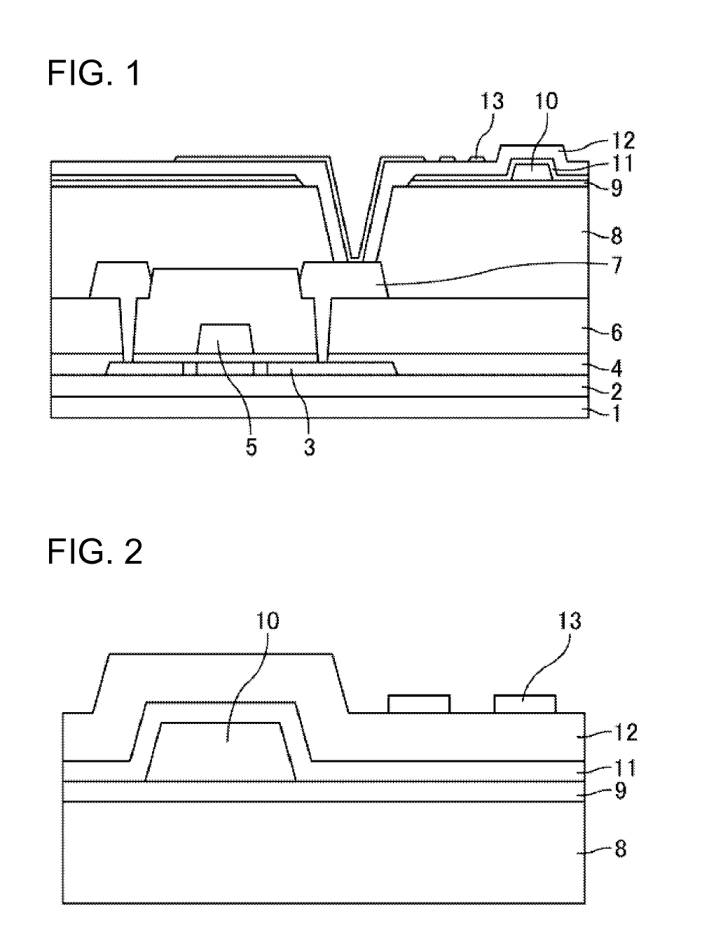

FIG. 1 is a cross-sectional view schematically showing the configuration of a thin film transistor used in a display panel substrate of this embodiment.

First, the configuration of a region where constituting elements of a TFT are not formed as shown in FIG. 1 is described. That is, a buffer film 2, a gate insulating film 4, a buffer film 6, a transparent resin film 8 are layered in this order on a glass substrate 1.

Next, the configuration of a region where constituting elements of a TFT are formed as shown in FIG. 1 is described. That is, in addition to the layered structure described above, a Si semiconductor layer 3, which will be the channel of the TFT, is formed on the buffer film 2, and a gate insulating film 4 is formed on the Si semiconductor layer 3. Also, on the gate insulating film 4, a gate electrode 5 is formed, and a butter film 6 is formed on the gate electrode 5. Further, a source electrode 7s extends from the top surface of the Si semiconductor layer 3 into the transparent resin film 8 through the gate insulating film 4 and the buffer film 6. The source electrode 7s is connected to the upper electrode 13 through a contact hole.

Further, as shown in FIG. 1, in a region on the transparent resin film 8 where an auxiliary metal wiring 10 is not formed, a first lower electrode 9 (ITO), a second lower electrode 11 (IZO), and an insulating film 12 are layered, and an upper electrode 13 is formed on a portion of the insulating film 12. Also, in a region where the auxiliary metal wiring 10 is formed, as shown in the cross-sectional view of the substrate, the auxiliary metal wiring 10 is further disposed on the first lower electrode 9, and the second lower electrode 11 is formed to cover the auxiliary metal wiring 10. Although this configuration is preferred, the auxiliary metal wiring 10 may alternatively be disposed, for example, under the first lower electrode 9 or on the second lower electrode 11. When the display panel substrate includes the auxiliary metal wiring 10 on the lower electrode to reduce the resistance, by forming the second lower electrode 11 on the first lower electrode 9, adhesion between the top surface of the lower electrode and the insulating film 12 can be improved.

In Embodiment 1, it is particularly preferred that the buffer film 2 disposed under the semiconductor layer Si3 that will be the TFT channel is made of SiO₂/SiNO, SiO₂, or the like. Also, the semiconductor layer Si3 is preferably made of CGS, LPS, or α-Si. Further, the gate insulating film 4 is preferably made of SiO₂, SiN, SiN/SiO₂, or the like. The gate electrode 5 is preferably made of W/TaN, Mo, MoW, or Ti/Al. The buffer film 6 is preferably made of SiO₂/SiN, SiO₂/SiN/SiO₂, SiO₂, SiN, or the like. The source electrode 7s and the drain electrode are preferably made of Ti/Al/Ti, Ti/Al, TiN/Al/TiN, Mo/Al—Nd/Mo, or Mo/Al/Mo. The transparent resin film 8 is preferably made of an organic insulating film or the like. The auxiliary metal wiring 10 is preferably formed of at least one selected from the group consisting of aluminum and aluminum alloys. Among them, Al/Mo is particularly preferred. The insulating film 12 is preferably made of a silicon-containing inorganic insulating film. Among them, SiO₂, SiN, or SiNO is particularly preferred. The upper electrode 13 is preferably made of ITO or IZO. Also, the upper electrode 13 in the liquid crystal display device can be used to control the alignment of liquid crystals.

FIG. 2 is a cross-sectional view schematically showing the layered structure of the display panel substrate of this embodiment.

As shown in FIG. 1, in a region on the transparent resin film 8 where no auxiliary metal wiring is formed, the first lower electrode 9 (ITO), the second lower electrode 11 (IZO), and the insulating film 12 are layered, and the upper electrode 13 is formed on a portion of the insulating film 12. Also, the display panel substrate of Embodiment 1 further includes the auxiliary metal wiring 10 between the first lower electrode 9 and the second lower electrode 11, which is preferred. However, the auxiliary metal wiring 10 may alternatively be disposed, for example, under the first lower electrode 9 or on the second lower electrode 11. In this configuration, as described above, adhesion between the top surface of the lower electrode and the insulating film 12 can be improved.

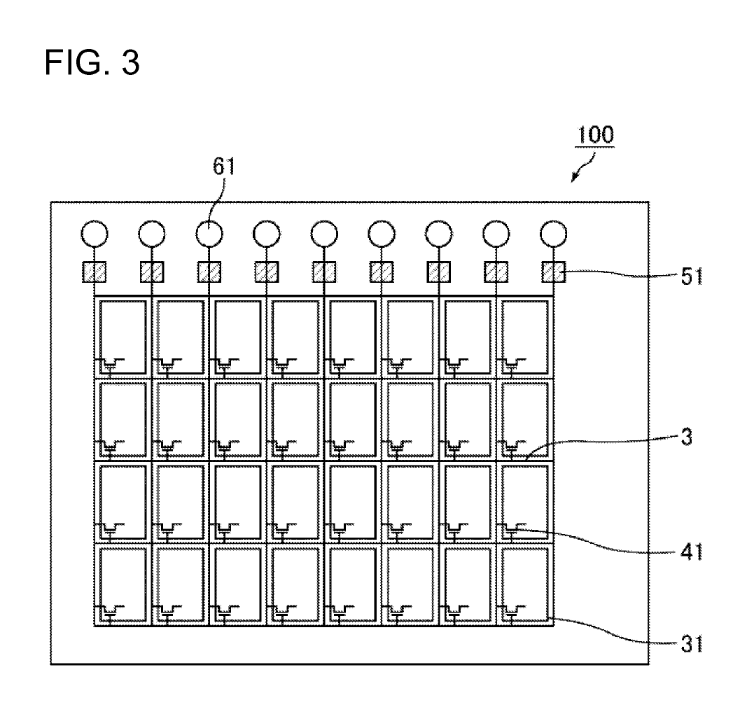

FIG. 3 is a plan view schematically showing the display panel substrate of this embodiment.

A display panel substrate 100 is a TFT side substrate on which thin film transistors (TFT) are disposed, and is composed of a pixel electrode area (display region) and a region outside the pixel electrode area (non-display region). In this embodiment, the display panel substrate is an active matrix type substrate using TFTs.

In the non-display region, connecting sections 51 and terminal sections 61 are disposed. A source driver can be mounted on the display panel substrate 100 through the connecting sections 51 with, for example, the chip-on-the-glass (COG) method. Also, flexible printed substrates (FPC) can be mounted on the circuit substrate 100 through the terminal sections 61. For example, a signal for driving the source driver can be inputted from FPC through the terminal sections 61 and 51.

In the display region of the display panel substrate 100, gate wirings and source wirings are disposed on the glass substrate such that they cross each other at about a right angle. Further, a pixel electrode and a TFT 41 are disposed in each region defined by a gate wiring and a source wiring. Also, drains formed of the source metal are disposed. Further, in Embodiment 1, a common electrode (not shown) is provided on the display panel substrate 100 on which thin film transistors (TFT) are disposed. It is preferable to apply the present invention to such a substrate. In particular, the configuration, where, as in Embodiment 1, the lower electrode is the common electrode and the upper electrode is the pixel electrode and the wiring, is preferred. Alternatively, the upper electrode may be the common electrode and the lower electrode may be the pixel electrode and the wiring.

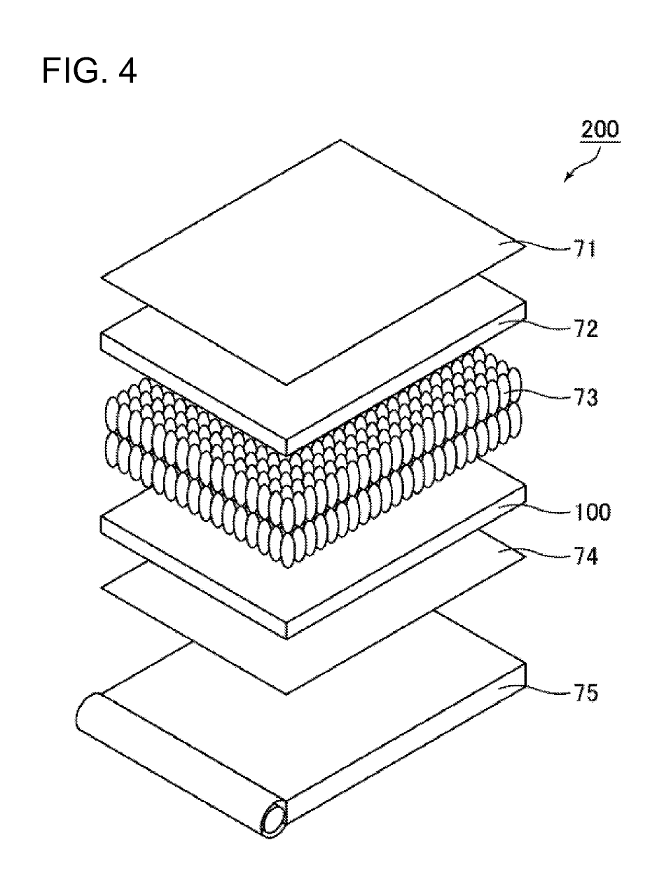

FIG. 4 is an exploded perspective view schematically showing the structure of a liquid crystal panel of the present embodiment. As shown in FIG. 4, a CF side substrate 72 and a display panel substrate 100 of a liquid crystal panel 200 hold liquid crystals 73 between them. The liquid crystal panel 200 has a backlight 75 at the back side of the display panel substrate 100. Light from the backlight 75 passes through a polarizing plate 74, a circuit substrate 100, the liquid crystals 73, the CF side substrate 72, and a polarizing plate 71 in this order. The light is transmitted or blocked through the control of the liquid crystal alignment.

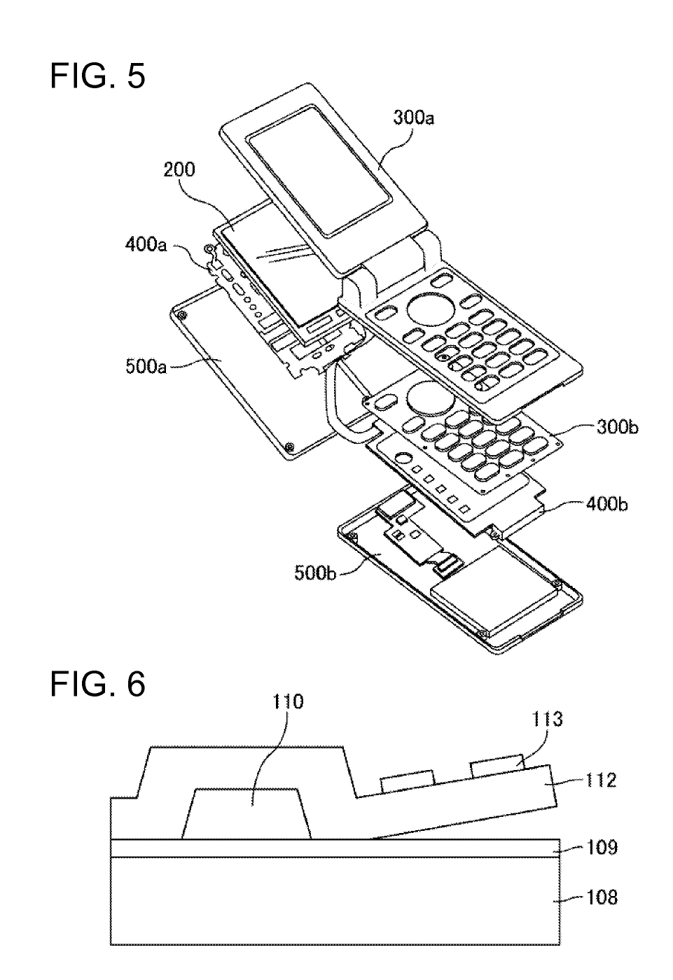

FIG. 5 is an exploded perspective view showing the structure of a liquid crystal display device (portable phone, for example) including the liquid crystal panel shown in FIG. 4. As shown in FIG. 4, the liquid crystal panel 200 and an electronic circuit section 400a are sealed in between a front cabinet 300a and a back cabinet top portion 500a. Similarly, a member 300b and an electronic circuit section 400b are sealed in between the front cabinet 300a and a back cabinet bottom portion 500b.

FIG. 4 and FIG. 5 show the configuration of a liquid crystal display device, but the display device of the present invention is not limited to the liquid crystal display device. Similar operational effects can also be obtained from EL display devices and the like such as organic EL display devices and inorganic EL display devices.

According to Embodiment 1, display panels and display devices including the display panel substrate can achieve a higher quality and performance such as better display quality, a higher yield, and improved reliability as a result of the significantly improved adhesion to the insulating film.

Configurations of the embodiments described above may appropriately be combined within the scope of the present invention.

The present application claims priority to Patent Application No. 2010-059860 filed in Japan on Mar. 16, 2010 under the Paris Convention and provisions of national law in a designated State. The entire contents of which are hereby incorporated by reference.

### Description of Reference Characters

1 glass substrate

2, 6 buffer film

3 Si semiconductor layer

4 gate insulating film

5 gate electrode

7 source electrode

8, 108 transparent resin film

9 first lower electrode

10, 110 auxiliary metal wiring

11 second lower electrode

12, 112 insulating film

13, 113 upper electrode

41 TFT

51 connecting section

61 terminal section

71, 74 polarizing plate

72 CF side substrate

73 liquid crystal

75 backlight

100 display panel substrate

109 lower electrode

200 liquid crystal panel

300a front cabinet

400a, 400b electronic circuit

500a top portion of the back cabinet

500b bottom portion of the back cabinet

1. A display panel substrate comprising, on a substrate, a lower electrode, an insulating film, and an upper electrode layered thereon in this order from a side of the substrate,
wherein said lower electrode includes a region in which an electrode made of indium tin oxide and an electrode made of indium zinc oxide, which are layered in this order from said substrate side.

2. The display panel substrate according to claim 1, further comprising an auxiliary metal wiring interposed between said substrate and said insulating film.

3. The display panel substrate according to claim 2, wherein said auxiliary metal wiring is formed of at least one selected from the group consisting of aluminum and aluminum alloys.

4. The display panel substrate according to claim 1, wherein said insulating film is a silicon-containing inorganic insulating film.

5. The display panel substrate according to claim 1, wherein said display panel substrate is an active matrix type substrate using thin film transistors.

6. A method for manufacturing a display panel substrate having, on a substrate, a lower electrode, an insulating film, and an upper electrode layered thereon in this order from a side of the substrate, the method comprising:
laminating a first lower electrode layer made of indium tin oxide and a second lower electrode layer made of indium zinc oxide in this order from the side of the substrate, and
wherein the first lower electrode layer and the second lower electrode layer are patterned with a same photomask.

7. A display panel comprising the display panel substrate according to claim 1.

8. A display device comprising the display panel according to claim 7.
